(19) United States
(12) Patent Application Publication
(10) Pub. No.: US 2025/0126831 A1
(43) Pub. Date: Apr. 17, 2025

(54) SEMICONDUCTOR DEVICE

(71) Applicant: Sony Semiconductor Solutions Corporation, Kanagawa (JP)

(72) Inventor: Tsuyoshi Suzuki, Kanagawa (JP)

(21) Appl. No.: 18/725,029

(22) PCT Filed: Dec. 2, 2022
(86) PCT No.: PCT/JP2022/044617

§ 371 Date: Jan. 7, 2025

(30) Foreign Application Priority Data
Jan. 28, 2022 (JP) 2022-011480

(51) Int. Cl. H10D 30/62

(52) U.S. Cl. CPC H10D 30/6213

(57) ABSTRACT

To further enhance a driving capability without depending on miniaturization of a fin structure.

A semiconductor device including: a channel layer extending from a main surface of a substrate in a normal direction of the main surface; a gate electrode provided across the channel layer in one direction in a plane of the main surface; and a gate insulating film interposed between the channel layer and the gate electrode, in which the channel layer has at least a pair of protruding structures protruding from both side surfaces in the one direction so as to form respective corners on a cut surface in the one direction, and a pair of recessed structures provided between the pair of protruding structures and the substrate.

### TECHNICAL FIELD

The present disclosure relates to a semiconductor device.

### BACKGROUND ART

In recent years, a fin field-effect transistor (FinFET) having a three-dimensional structure, which is capable of enhancing a driving capability as compared with a planar type metal-oxide-semiconductor field-effect transistor (MOSFET), has been put into practical use. In the FinFET, two or more surfaces of a channel are three-dimensionally surrounded by a gate, and a gate domination power over the channel is increased, so that the current driving capability can be improved.

For example, Patent Document 1 below discloses a FinFET in which five surfaces of a channel having a hexagonal cross-sectional shape are surrounded by a gate.

### CITATION LIST

### Patent Document

Patent Document 1: Japanese Patent Application Laid-Open No. 2005-203798

### SUMMARY OF THE INVENTION

### Problems to be Solved by the Invention

Such a FinFET can obtain a higher driving capability by further narrowing the width of a fin structure, which is a channel. However, further miniaturization of the fin structure further increases the difficulty and cost of the manufacturing process of the FinFET.

Therefore, the present disclosure proposes a novel and improved semiconductor device capable of improving a driving capability without depending on miniaturization of a fin structure.

### Solutions to Problems

According to the present disclosure, there is provided a semiconductor device including: a channel layer extending from a main surface of a substrate in a normal direction of the main surface; a gate electrode provided across the channel layer in one direction in a plane of the main surface; and a gate insulating film interposed between the channel layer and the gate electrode, in which the channel layer has at least a pair of protruding structures protruding from both side surfaces in the one direction so as to form respective corners on a cut surface in the one direction, and a pair of recessed structures provided between the pair of protruding structures and the substrate.

### BRIEF DESCRIPTION OF DRAWINGS

FIG. 1 is a transparent perspective view illustrating an overall configuration of a semiconductor device according to an embodiment of the present disclosure.

FIG. 2 is a longitudinal cross-sectional view illustrating a cross-sectional configuration of the semiconductor device illustrated in FIG. 1.

FIG. 3 is a schematic diagram for describing each of regions set in a protruding structure of a channel layer.

FIG. 4 is a schematic diagram for describing a method of deriving formulas expressing electric fields of the regions illustrated in FIG. 3.

FIG. 5 is a graph illustrating a correspondence relationship between an angle of a vertex angle of the protruding structure and an electric field intensity applied to the protruding structure.

FIG. 6 is a graph illustrating a correspondence relationship between a shape factor α expressing the electric field intensity depending on the shape of the channel layer and the angle of the vertex angle of the protruding structure.

FIG. 7 is a longitudinal cross-sectional view illustrating a cross-sectional configuration of a semiconductor device according to a first modification in a channel width direction.

FIG. 8 is a longitudinal cross-sectional view illustrating a cross-sectional configuration of a semiconductor device according to a second modification in the channel width direction.

FIG. 9 is a longitudinal cross-sectional view illustrating a cross-sectional configuration of a semiconductor device according to a third modification in the channel width direction.

FIG. 10 is a longitudinal cross-sectional view illustrating a cross-sectional configuration of a semiconductor device according to a fourth modification in the channel width direction.

### MODE FOR CARRYING OUT THE INVENTION

Hereinafter, a preferred embodiment of the present disclosure will be described in detail with reference to the accompanying drawings. Note that, in the present specification and the drawings, components having substantially the same functional configuration are denoted by the same reference signs, and redundant description is omitted.

Note that the description will be given in the following order.
1. Configuration example
2. Actions and effects
3. Modifications

### 1. Configuration Example

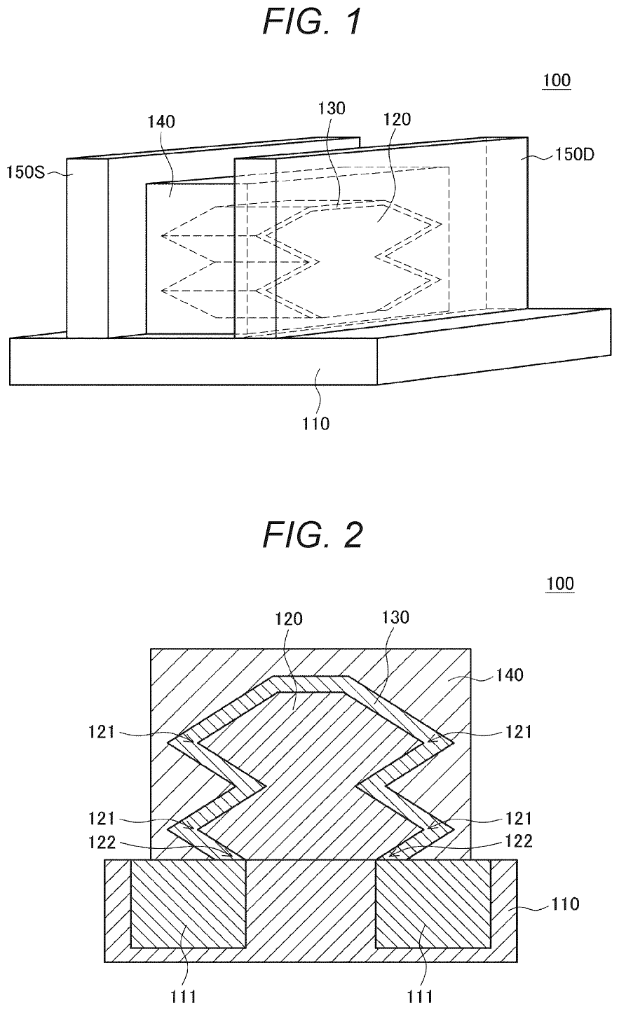

First, a configuration example of a semiconductor device according to an embodiment of the present disclosure will be described with reference to FIGS. 1 and 2. FIG. 1 is a transparent perspective view illustrating an overall configuration of a semiconductor device 100 according to the present embodiment. FIG. 2 is a longitudinal cross-sectional view illustrating a cross-sectional configuration of the semiconductor device 100 illustrated in FIG. 1. Note that the cross section illustrated in FIG. 2 is a cross section obtained by cutting the semiconductor device 100 in a channel width (or fin width) direction.

As illustrated in FIG. 1, the semiconductor device 100 includes, for example, a substrate 110, a channel layer 120, a gate electrode 140, a gate insulating film 130, a source layer 150S, and a drain layer 150D.

The substrate 110 is a support of the semiconductor device 100. The substrate 110 may be, for example, a substrate including Si, SiGe, SiC, or a III-V compound semiconductor. Furthermore, as illustrated in FIG. 2, the substrate 110 is provided with an element isolation layer 111 including an insulating material. The element isolation layer 111 is provided by the insulating material being embedded in a part of the substrate 110, and can electrically isolate the semiconductor device 100 from other elements.

The channel layer 120 includes a semiconductor material, and is provided to extend from a main surface of the substrate 110 in a normal direction of the main surface. The channel layer 120 may include, for example, Si, SiGe, SiC, or a III-V compound semiconductor into which a conductive impurity is introduced. In order to reduce lattice defects, the channel layer 120 preferably includes a semiconductor material having a lattice constant close to that of the semiconductor material included in the substrate 110. For example, the channel layer 120 may include the same semiconductor material as the semiconductor material included in the substrate 110.

As illustrated in FIG. 2, in the semiconductor device 100 according to the present embodiment, the channel layer 120 has at least a pair of protruding structures 121 protruding from both side surfaces in the channel width direction so as to form corners. The protruding structures 121 are provided so as to protrude from the side surfaces of the channel layer 120 such that recessed structures 122 are formed between the protruding structures 121 and the substrate 110, and each have a ridge line formed by two surfaces inclined in the normal direction of the main surface of the substrate 110.

That is, the shape of a cut surface of each of the protruding structures 121 in the channel width direction (cross-sectional shape illustrated in FIG. 2) is a triangular shape in which a vertex angle protruding from a side surface of the channel layer 120 is an acute angle, a right angle, or an obtuse angle. Furthermore, the shape of the protruding structure 121 in a channel length direction orthogonal to the channel width direction is a triangular prism shape having the above-described triangular shape as a bottom surface.

In such a case, in the protruding structure 121, electric fields are applied from the gate electrode 140 to the channel layer 120 on two inclined surfaces forming the protruding structure 121. According to this structure, in the protruding structure 121, the electric fields from the two inclined surfaces are superimposed and applied to the channel layer 120, so that a stronger electric field can be applied to the channel layer 120 even at the same gate voltage. Therefore, the semiconductor device 100 can improve a gate domination power over the channel layer 120, and thus can improve a current driving capability.

The vertex angle of the triangular shape of the protruding structure 121 in the channel width direction is preferably an angle of 60 degrees or more and 150 degrees or less, and more preferably an angle of 60 degrees or more and 90 degrees or less. In such a case, the semiconductor device 100 can apply a stronger electric field to the channel layer 120 even with the same gate voltage, as will be described in detail in the section of actions and effects in the subsequent stage, so that the current driving capability can be improved.

Furthermore, a plurality of pairs of protruding structures 121 may be provided to protrude from both side surfaces of the channel layer 120 so as to overlap in the normal direction of the main surface of the substrate 110. In such a case, the outer shape of a cut surface of the channel layer 120 in the channel width direction is a zigzag shape (that is, the shape of a saw blade) with the plurality of protruding structures 121. According to this structure, the semiconductor device 100 can apply a stronger electric field to the channel layer 120 in each of the plurality of pairs of protruding structures 121, and thus can improve the current driving capability in proportion to the number of formed protruding structures 121.

Note that the pair of protruding structures 121 may protrude from both side surfaces of the channel layer 120 at the same height. In such a case, in the semiconductor device 100, the pair of protruding structures 121 can be simultaneously formed on both side surfaces of the channel layer 120 in the same process, and thus the channel layer 120 having the pair of protruding structures 121 can be more easily formed.

The channel layer 120 as described above may be formed, for example, by epitaxially growing the above-described semiconductor material as a single crystal. Specifically, the channel layer 120 may be formed by epitaxial growth of the semiconductor material in which crystal growth is controlled such that two surfaces forming each of the protruding structures 121 become crystal planes of the semiconductor material.

For example, each of the protruding structures 121 may be formed by epitaxially growing the semiconductor material such that a lower surface of the protruding structure 121 becomes a crystal plane, then changing process conditions, and epitaxially growing the semiconductor material such that an upper surface of the protruding structure 121 becomes a crystal plane. Furthermore, the plurality of pairs of protruding structures 121 illustrated in FIG. 2 may be formed by planarizing an upper end portion of the channel layer 120 after forming one of the pairs of protruding structures 121 by chemical mechanical polishing (CMP) or the like and then repeatedly performing the above-described epitaxial growth.

However, the channel layer 120 may be formed by a method other than the epitaxial growth using crystal plane orientation. For example, the channel layer 120 may be formed by use of various microfabrication processes such as lithography, vapor deposition such as chemical vapor deposition (CVD) or atomic layer deposition (ALD), and etching.

The gate electrode 140 includes a conductive material, and is provided so as to straddle the channel layer 120 in the channel width direction of the channel layer 120 (that is, the direction in which the protruding structures 121 of the channel layer 120 protrude). The gate electrode 140 may include, for example, a conductive material containing a simple substance or a compound such as Si, poly-Si, Al, Cu, Au, W, Ta, Ti, Mo, or Ru. The gate electrode 140 is in contact with the channel layer 120 via the gate insulating film 130 on the two surfaces forming the corner of each of the protruding structures 121 of the channel layer 120, so that electric fields can be applied to the protruding structure 121 of the channel layer 120 from the two surfaces of the upper surface and the lower surface.

The gate insulating film 130 includes an insulating material, and is provided to be interposed between the channel layer 120 and the gate electrode 140. Specifically, the gate insulating film 130 may be provided so as to cover the surface of the channel layer 120 in the channel width direction. The gate insulating film 130 may include, for example, SiOₓ, SiN, or SiON, or may include a high dielectric constant material (high-k material) such as HfOₓ, HfAlON, Y₂O₃, ZrOₓ, Al₂O₃, or NbOₓ.

As another example, the gate insulating film 130 may include an oxide of the semiconductor material included in the channel layer 120. In such a case, in the semiconductor device 100, the gate insulating film 130 can be easily formed by surface oxidation of the channel layer 120, and thus the manufacturing process can be further simplified.

The source layer 150S and the drain layer 150D are provided so as to be in contact with the channel layer 120 on both side surfaces of the channel layer 120 in the channel length direction (that is, in the direction orthogonal to the channel width direction). Furthermore, the source layer 150S and the drain layer 150D are electrically insulated from the gate electrode 140 by a gap or an insulating layer being provided therebetween. For example, the source layer 150S and the drain layer 150D may include a semiconductor material such as Si, SiGe, or Ge epitaxially grown with an impurity of a conductivity type different from that of the channel layer 120 introduced.

### 2. Actions and Effects

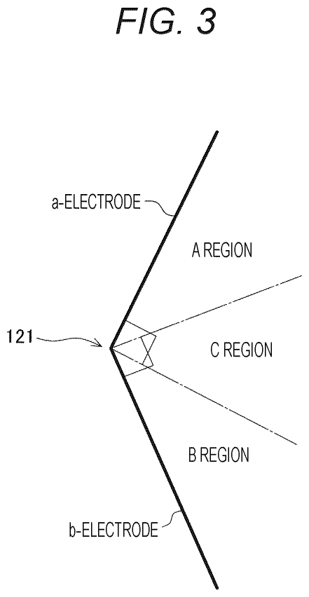

Next, actions and effects of the semiconductor device 100 according to the present embodiment will be described in more detail with reference to FIGS. 3 to 7.

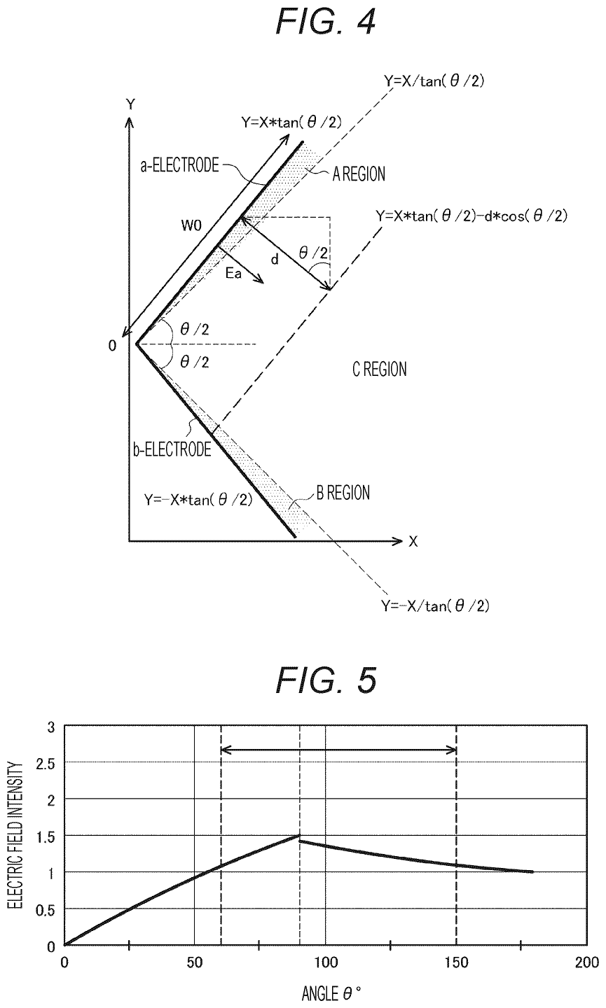

First, an electric field applied to one of the protruding structures 121 of the channel layer 120 will be described with reference to FIGS. 3 and 4. FIG. 3 is a schematic diagram for describing each of regions set in the protruding structure 121 of the channel layer 120. FIG. 4 is a schematic diagram for describing a method of deriving formulas expressing electric fields of the regions illustrated in FIG. 3.

As illustrated in FIG. 3, the electric field applied to the protruding structure 121 protruding from a side surface of the channel layer 120 can be considered to be divided into three regions of an A region, a B region, and a C region. The C region is a region where a region spreading in a vertical direction of an a-electrode on an upper surface forming the protruding structure 121 and a region spreading in a vertical direction of a b-electrode on a lower surface forming the protruding structure 121 overlap each other. The A region is a region obtained by excluding the C region from the region spreading in the vertical direction of the a-electrode on the upper surface forming the protruding structure 121. The B region is a region obtained by excluding the C region from the region spreading in the vertical direction of the b-electrode on the lower surface forming the protruding structure 121.

Here, in a FinFET, the concentration of the conductive impurity in the channel layer 120 is low, and thus an electric field generated by a charge of the conductive impurity in the channel layer 120 is approximately ignored. Therefore, an electric field generated from the gate electrode 140 can be regarded as a constant electric field in a depth direction generated by one parallel plate electrode.

When coordinates and variables are set as illustrated in FIG. 4, an electric field generated from the a-electrode can be expressed by Formula 1 below. Note that L is a gate length, Q is a charge given to the gate electrode 140, and ε is a dielectric constant.

$$\begin{matrix}[ Math . 1 ] & \\ \vert Ea \vert = Q / ( ε L ( W 0 + d ) ) & ( Formula 1 )\end{matrix}$$

Therefore, an electric field intensity Ea′ on an equipotential surface of the electric field generated by the a-electrode can be approximately expressed by Formula 2 below.

$$\begin{matrix}[ Math . 2 ] & \\ {Ea}^{′} = Q / ( ε L ( W 0 + d * ( θ - π / 2 ) + d * π / 2 ) ) = Ea * ( W 0 + d * π ) / ( W 0 + d * θ ) & ( Formula 2 )\end{matrix}$$

Therefore, in a summation region of the A region and the C region (Y<X*tan (θ/2), Y>−X/tan (θ/2)), an electric field intensity (Eax, Eay) generated by the a-electrode is expressed by Formulas 3 below.

$$\begin{matrix}[ Math . 3 ] & \\ Eax = ( Ea * ( W 0 + d * π ) / ( W 0 + d * θ ) ) * sin ( θ / 2 ) \\ Eay = - ( Ea * ( W 0 + d * π ) / ( W 0 + d * θ ) ) * cos ( θ / 2 ) & ( Formulas 3 )\end{matrix}$$

Furthermore, in the B region (Y>−X*tan (θ/2), Y<−X/tan (θ/2)), the electric field intensity (Eax, Eay) generated by the a-electrode is expressed by Formulas 4 below (where d=√(x\hat{ }2+y\hat{ }2)).

$$\begin{matrix}[ Math . 4 ] & \\ Eax = ( Ea * ( W 0 + d * π ) / ( W 0 + d * θ ) ) * ( x / d ) \\ Eay = ( Ea * ( W 0 + d * π ) / ( W 0 + d * θ ) ) * ( y / d ) & ( Formulas 4 )\end{matrix}$$

An electric field intensity generated by the b-electrode can be similarly considered. Therefore, when the electric field intensities generated by the a-electrode and the b-electrode are synthesized with |Ea|=|Eb|=E0, in the A region (Y<X*tan (θ/2), Y>X/tan (θ/2)), the total of the electric field intensities generated by the a-electrode and the b-electrode (Ex, Ey) is expressed by Formulas 5 below (where d=√(x\hat{ }2+y\hat{ }2)).

$$\begin{matrix}[ Math . 5 ] & \\ Ex = ( E 0 * ( W 0 + d * π ) / ( W 0 + d * θ ) ) * ( x / d + sin ( θ / 2 ) ) \\ Ey = ( E 0 * ( W 0 + d * π ) / ( W 0 + d * θ ) ) * ( y / d - cos ( θ / 2 ) ) & ( Formulas 5 )\end{matrix}$$

Furthermore, in the B region (Y>−X*tan (θ/2), Y<−X/tan (θ/2)), the total of the electric field intensities generated by the a-electrode and the b-electrode (Ex, Ey) is expressed by Formulas 6 below (where d=√(x\hat{ }2+y\hat{ }2)).

$$\begin{matrix}[ Math . 6 ] & \\ Ex = ( E 0 * ( W 0 + d * π ) / ( W 0 + d * θ ) ) * ( x / d + sin ( θ / 2 ) ) \\ Ey = ( E 0 * ( W 0 + d * π ) / ( W 0 + d * θ ) ) * ( y / d - cos ( θ / 2 ) ) & ( Formulas 6 )\end{matrix}$$

Furthermore, in the C region (Y<X/tan (θ/2), Y>−X/tan (θ/2)), the total of the electric field intensities generated by the a-electrode and the b-electrode (Ex, Ey) is expressed by Formulas 7 below (where d=(X*tan (θ/2)−Y)/cos (θ/2)).

$$\begin{matrix}[ Math . 7 ] & \\ Ex = 2 E 0 * ( E 0 * ( W 0 + d * π ) / ( W 0 + d * θ ) ) * sin ( θ / 2 ) \\ Ey = 0 & ( Formulas 7 )\end{matrix}$$

FIG. 5 illustrates a relationship between the electric field intensity applied to the protruding structure 121 calculated on the basis of Formulas 5 to 7 described above and the angle of the vertex angle of the protruding structure 121 protruding from the side surface of the channel layer 120. FIG. 5 is a graph illustrating a correspondence relationship between the electric field intensity applied to the protruding structure 121 and the angle of the vertex angle of the protruding structure 121. Note that the electric field intensity on the vertical axis in FIG. 5 is expressed by a relative value in which the electric field intensity in the case of an angle of 180° (that is, in a case where the protruding structure 121 is not formed) is 1.

Note that, in the angle range of more than 0° and 90° or less, the entire protruding structure 121 functions as a channel, and thus the electric field intensity acting on the channel is the electric field intensity of the C region expressed by Formulas 7. On the other hand, in the angle range of more than 90° and 180° or less, the outermost surface of the protruding structure 121 functions as a channel, and thus the electric field intensity acting on the channel is the total of the electric field intensity of the A region expressed by Formulas 5 and the electric field intensity of the B region expressed by Formulas 6.

As illustrated in FIG. 5, it can be seen that the electric field intensity acting on the protruding structure 121 is higher in a case where the angle of the vertex angle of the protruding structure 121 is in a range of 60° or more and 150° or less than in a case where the angle is 180° (in a case where the protruding structure 121 is not formed). Therefore, the semiconductor device 100 can further enhance the gate domination power when the angle of the vertex angle of the protruding structure 121 is in the range of 60° or more and 150° or less. In particular, when the angle of the vertex angle of the protruding structure 121 is in a range of 60° or more and 90° or less, the semiconductor device 100 can cause the entire protruding structure 121 to function as a channel, and thus it is also possible to further reduce the on-resistance in the channel layer 120.

Furthermore, when a manner of applying an electric field to the channel layer 120 depending on the shape is expressed as a shape factor α, a current I flowing when the semiconductor device 100 is in the on state can be modeled as in Formula 8 below. Note that μ is a charge mobility, C is a gate capacitance, W is a gate width, and L is a gate length. Vg is a gate voltage, Vth is a threshold voltage, and Vd is a drain voltage.

$$\begin{matrix}[ Math . 8 ] & \\ I = μ CW / L [ α ( Vg - Vth - Vd / 2 ) ] * Vd & ( Formulas 8 )\end{matrix}$$

According to Formula 8 described above, in the semiconductor device 100, a transconductance gm expressing the change amount of a drain current with respect to the gate voltage is expressed as gm=μCW/L*α*Vd as a coefficient of (Vg−Vth−Vd/2). On the other hand, a transconductance gm₀ of a normal FinFET (that is, in a case where the angle of the vertex angle of the protruding structure is) 180° is gm₀=μCW/L*Vd. Therefore, the transconductance gm of the semiconductor device 100 is expressed as gm=gm₀*α using the transconductance gm₀ of the normal FinFET.

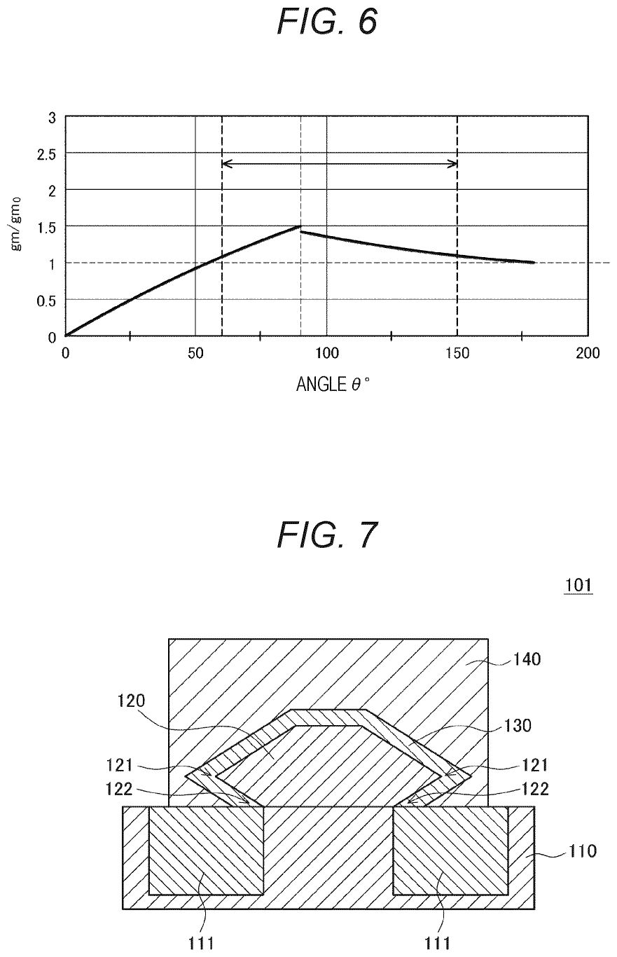

That is, a correspondence relationship between the shape factor α expressing the electric field intensity depending on the shape of the channel layer 120 and the angle of the vertex angle of the protruding structure 121 described above is as illustrated in the graph of FIG. 6. FIG. 6 is a graph illustrating the correspondence relationship between the shape factor α expressing the electric field intensity depending on the shape of the channel layer 120 and the angle of the vertex angle of the protruding structure 121.

As illustrated in FIG. 6, it can be seen that the shape factor α (gm/gm₀) is higher in a case where the angle of the vertex angle of the protruding structure 121 is in the range of 60° or more and 150° or less than in a case where the angle is 180° (in a case of the normal FinFET in which the protruding structure 121 is not formed). Therefore, it can be seen that the semiconductor device 100 can enhance the transconductance in a case where the angle of the vertex angle of the protruding structure 121 is in the range of 60° or more and 150° or less as compared with the normal FinFET, and thus can obtain a higher current driving capability than the normal FinFET.

As described above, in the semiconductor device 100 according to the present embodiment, forming the protruding structures 121 makes it possible to improve the current driving capability without reducing the width of the channel layer 120. The semiconductor device 100 according to the present embodiment is used for an amplifier transistor of a pixel in a solid-state imaging device such as a CMOS image sensor, for example, so that the pixel can be driven at a higher speed.

### 3. Modifications

Next, first to fourth modifications of the semiconductor device 100 according to the present embodiment will be described with reference to FIGS. 7 to 10.

### First Modification

FIG. 7 is a longitudinal cross-sectional view illustrating a cross-sectional configuration of a semiconductor device 101 according to the first modification in the channel width direction. As illustrated in FIG. 7, in the semiconductor device 101, the channel layer 120 may have only one pair of protruding structures 121. Even in such a case, the semiconductor device 101 can apply a strong electric field to the channel layer 120 in each of the protruding structures 121, and thus improves the gate domination power over the channel layer 120, so that it is possible to improve the current driving capability.

The number of pairs of protruding structures 121 provided in the channel layer 120 can be appropriately selected according to the balance between the required current driving capability and the cost of the process of forming the channel layer 120. For example, as the number of pairs of protruding structures 121 provided in the channel layer 120 increases, the gate domination power over the channel layer 120 can be improved, but the cost increases as the number of steps of the process of forming the channel layer 120 increases. Therefore, in order to further reduce the cost of the process of forming the channel layer 120, the number of pairs of protruding structures 121 may be one. On the other hand, in order to further improve the gate domination power over the channel layer 120, the number of pairs of protruding structures 121 may be three.

### Second Modification

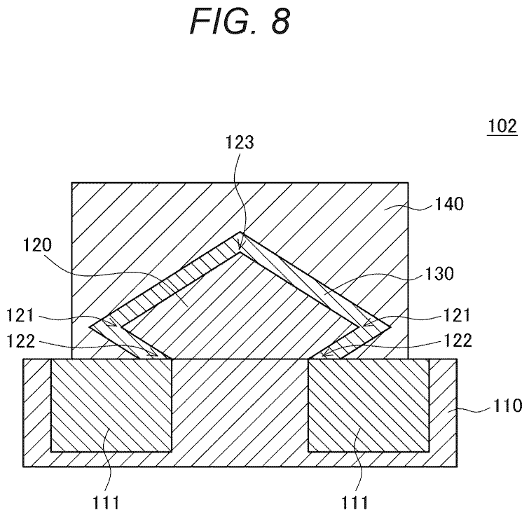

FIG. 8 is a longitudinal cross-sectional view illustrating a cross-sectional configuration of a semiconductor device 102 according to the second modification in the channel width direction. As illustrated in FIG. 8, in the semiconductor device 102, an upper end portion of the channel layer 120 in an extending direction may not be flattened, and may be provided as a ridge portion 123 protruding with a corner formed. Specifically, the upper end portion of the channel layer 120 in the extending direction may be provided as the ridge portion 123 including a ridge line formed by an inclined upper surface of the protruding structure 121 protruding from one side surface and an inclined upper surface of the protruding structure 121 protruding from the other side surface. In such a case, in the ridge portion 123, the ridge line including both upper surfaces of the pair of protruding structures 121 extends in the channel length direction.

According to the second modification, the semiconductor device 102 can omit a process of planarizing the upper end portion of the channel layer 120 by CMP or the like after forming the channel layer 120 having the pair of protruding structures 121. Therefore, the semiconductor device 102 can further reduce the cost of the process of forming the channel layer 120.

### Third Modification

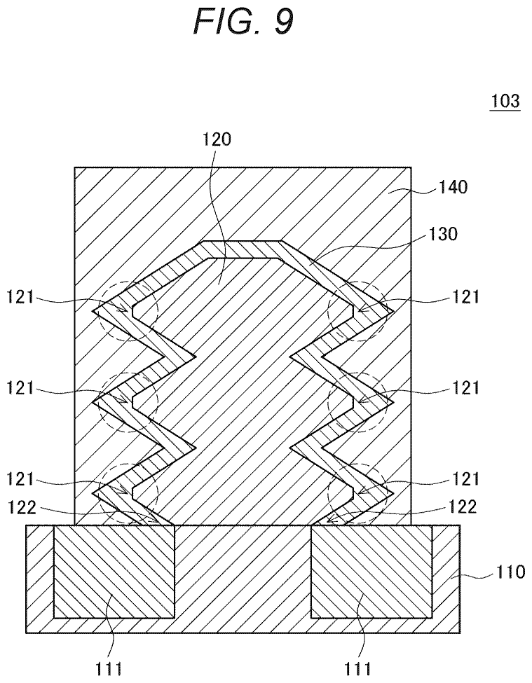

FIG. 9 is a longitudinal cross-sectional view illustrating a cross-sectional configuration of a semiconductor device 103 according to the third modification in the channel width direction. As illustrated in FIG. 9, in the semiconductor device 103, each of the protruding structures 121 may be provided with a chamfered vertex angle (that is, with a rounded corner) protruding from a side surface of the channel layer 120. For example, the protruding structure 121 may be provided by forming the channel layer 120 by epitaxial growth using crystal plane orientation and then rounding the corner by etching or thermal oxidation.

According to the third modification, the semiconductor device 103 can prevent excessive electric field concentration from occurring at the vertex angle of the protruding structure 121 protruding from the side surface of the channel layer 120. Therefore, the semiconductor device 103 can suppress breakdown or the like of the gate insulating film 130 due to excessive electric field concentration, and thus can further improve the reliability during operation.

### Fourth Modification

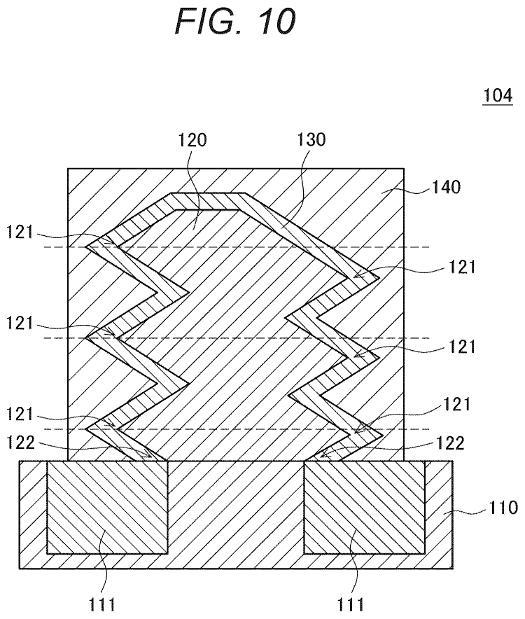

FIG. 10 is a longitudinal cross-sectional view illustrating a cross-sectional configuration of a semiconductor device 104 according to the fourth modification in the channel width direction. As illustrated in FIG. 10, in the semiconductor device 104, the pair of protruding structures 121 may protrude from both side surfaces of the channel layer 120 at different heights. Even in such a case, the semiconductor device 104 can similarly apply a strong electric field to the channel layer 120 in each of the protruding structures 121, and thus can improve the current driving capability.

Although the preferred embodiment of the present disclosure has been described above in detail with reference to the accompanying drawings, the technical scope of the present disclosure is not limited to such an example. It is obvious that a person having ordinary knowledge in the technical field of the present disclosure can conceive various changes or modifications within the scope of the technical idea described in the claims, and it is naturally understood that these also fall within the technical scope of the present disclosure.

Furthermore, the effects described in the present specification are merely illustrative or exemplary, and are not restrictive. That is, the technology according to the present disclosure can exhibit other effects obvious to those skilled in the art from the description of the present specification, together with or instead of the above effects.

Note that the following configurations also fall within the technical scope of the present disclosure.

(1)

A semiconductor device including:
a channel layer extending from a main surface of a substrate in a normal direction of the main surface;
a gate electrode provided across the channel layer in one direction in a plane of the main surface; and
a gate insulating film interposed between the channel layer and the gate electrode,
in which
the channel layer has at least a pair of protruding structures protruding from both side surfaces in the one direction so as to form respective corners on a cut surface in the one direction, and a pair of recessed structures provided between the pair of protruding structures and the substrate.

(2)

The semiconductor device according to (1), in which a size of the corner of each of the protruding structures is 60° or more and 150° or less.

(3)

The semiconductor device according to (2), in which the size of the corner of each of the protruding structures is 60° or more and 90° or less.

(4)

The semiconductor device according to any one of (1) to (3), in which the gate electrode is in contact with the channel layer via the gate insulating film on two surfaces forming the corner of each of the protruding structures.

(5)

The semiconductor device according to any one of (1) to (4), in which the corner of each of the protruding structures is chamfered.

(6)

The semiconductor device according to any one of (1) to (5), in which a plurality of the pairs of protruding structures is provided in the normal direction.

(7)

The semiconductor device according to any one of (1) to (6), in which each of the pair of protruding structures protrudes from a same height of both the side surfaces in the one direction.

(8)

The semiconductor device according to any one of (1) to (6), in which each of the pair of protruding structures protrudes from a different height of both the side surfaces in the one direction.

(9)

The semiconductor device according to any one of (1) to (8), in which an end portion of the channel layer in the normal direction is flat.

(10)

The semiconductor device according to any one of (1) to (9), further including a source layer and a drain layer that are in contact with the channel layer on both side surfaces of the channel layer in a direction orthogonal to the one direction.

(11)

The semiconductor device according to any one of (1) to (10), in which the channel layer includes a single crystal semiconductor.

(12)

The semiconductor device according to (11), in which the semiconductor includes Si, SiGe, SiC, or a III-V compound semiconductor.

(13)

The semiconductor device according to (11) or (12), in which two surfaces forming the corner of each of the protruding structures include a crystal plane of the semiconductor.

### REFERENCE SIGNS LIST

100, 101, 102, 103, 104 Semiconductor device
110 Substrate
111 Element isolation layer
120 Channel layer
121 Protruding structure
122 Recessed structure
123 Ridge portion
130 Gate insulating film
140 Gate electrode
150D Drain layer
150S Source layer

1. A semiconductor device comprising:
a channel layer extending from a main surface of a substrate in a normal direction of the main surface;
a gate electrode provided across the channel layer in one direction in a plane of the main surface; and
a gate insulating film interposed between the channel layer and the gate electrode,
wherein
the channel layer has at least a pair of protruding structures protruding from both side surfaces in the one direction so as to form respective corners on a cut surface in the one direction, and a pair of recessed structures provided between the pair of protruding structures and the substrate.

2. The semiconductor device according to claim 1, wherein a size of the corner of each of the protruding structures is 60° or more and 150° or less.

3. The semiconductor device according to claim 2, wherein the size of the corner of each of the protruding structures is 600 or more and 90° or less.

4. The semiconductor device according to claim 1, wherein the gate electrode is in contact with the channel layer via the gate insulating film on two surfaces forming the corner of each of the protruding structures.

5. The semiconductor device according to claim 1, wherein the corner of each of the protruding structures is chamfered.

6. The semiconductor device according to claim 1, wherein a plurality of the pairs of protruding structures is provided in the normal direction.

7. The semiconductor device according to claim 1, wherein each of the pair of protruding structures protrudes from a same height of both the side surfaces in the one direction.

8. The semiconductor device according to claim 1, wherein each of the pair of protruding structures protrudes from a different height of both the side surfaces in the one direction.

9. The semiconductor device according to claim 1, wherein an end portion of the channel layer in the normal direction is flat.

10. The semiconductor device according to claim 1, further comprising a source layer and a drain layer that are in contact with the channel layer on both side surfaces of the channel layer in a direction orthogonal to the one direction.

11. The semiconductor device according to claim 1, wherein the channel layer includes a single crystal semiconductor.

12. The semiconductor device according to claim 11, wherein the semiconductor includes Si, SiGe, SiC, or a III-V compound semiconductor.

13. The semiconductor device according to claim 11, wherein two surfaces forming the corner of each of the protruding structures include a crystal plane of the semiconductor.
